(19) United States
(12) Patent Application Publication
(10) Pub. No.: US 2022/0145443 A1
(43) Pub. Date: May 12, 2022

(54) VAPOR DEPOSITION UNIT AND VACUUM VAPOR DEPOSITION APPARATUS PROVIDED WITH VAPOR DEPOSITION UNIT

(71) Applicant: ULVAC, INC., Kanagawa (JP)

(72) Inventors: Shuuji Saitou, Kanagawa (JP); Akihiro Yokoyama, Kanagawa (JP)

(73) Assignee: ULVAC, INC., Kanagawa (JP)

(21) Appl. No.: 17/605,106

(22) PCT Filed: Dec. 27, 2019
(86) PCT No.: PCT/JP2019/051373

§ 371 Date: Oct. 20, 2021

(30) Foreign Application Priority Data
May 13, 2019 (JP) 2019-090499

(51) Int. Cl. C23C 14/26; C23C 14/24

(52) U.S. Cl. CPC C23C 14/26; C23C 14/243

(57) ABSTRACT

A vapor deposition unit of this invention is provided with: a container box for containing therein a vapor deposition material; and a heating means for heating the vapor deposition material inside the container box, and which has formed in one plane of the container box a discharge opening for discharging a sublimated or evaporated vapor deposition material as a result of heating. The vapor deposition unit is further provided, inside a storing chamber, with a moving means for moving the vapor deposition unit. Provided that a direction looking toward the opening in the storing chamber is defined as an upper side, the moving means moves the vapor deposition unit disposed in the storing chamber in an up-and-down direction in a posture coinciding with a phase of the discharge opening.

### TECHNICAL FIELD

The present invention relates to a vapor deposition unit comprising: a container box for containing therein a vapor deposition material; and a heating means for heating the vapor deposition material inside the container box; the container box having formed through one surface thereof a discharge opening for discharging the vapor deposition material that has been sublimated or vaporized by heating. This invention also relates to a vacuum vapor deposition apparatus provided with this vapor deposition unit. In particular, this invention relates to one suitable for forming a film on a sheet-like base material that is wound around a can-roller.

### BACKGROUND ART

The vapor deposition unit which performs film forming on an object to be vapor deposited such as a sheet-like base material or substrate which is of relatively large width and which moves (travels), e.g., at a predetermined speed, is known, e.g., in patent document 1. This vapor deposition unit is provided with: a container box for containing therein a vapor deposition material; and a heating means for heating the vapor deposition material inside the container box. In a lid portion of the container box (upper surface), tubular discharge openings are arrayed side by side with, and at a distance from, one another in the widthwise direction of the base material (so-called line source). In this arrangement by heating the container box inside the vacuum chamber (main chamber) which is in vacuum atmosphere, sublimated or evaporated vapor deposition material is discharged out of each of the discharge openings according to a predetermined cosine law and are splashed and vapor-deposited while spreading in a dome shape out of the discharge openings.

The container box of this kind of vapor deposition unit is ordinarily disposed in a fixed manner inside the vacuum chamber. Therefore, in designing the vacuum vapor deposition apparatus by assembling together the vapor deposition unit, it is normal practice to set the distance between the discharge openings and the object to be vapor deposited by taking into consideration the kind of vapor deposition material to be used and the fly distribution of the vapor deposition material depending on the amount of heating from the heating means per unit time relative to the container box. However, even the same vapor deposition material, the amount of vapor deposition material that is sublimated or evaporated inside the container box may vary with the amount of heating (heating temperature). On the other hand, in case of different vapor deposition materials, even if the amount of heating is appropriately controlled so as to make coincide the amounts of vapor deposition materials to be sublimated or evaporated inside the container box, the fly distribution may vary depending on the kinds of the vapor deposition materials. It follows that the arrangement of fixedly disposing the container box inside the vacuum chamber lacks in versatility. In addition, at the time of vapor deposition, the vapor deposition material gets adhered to, and deposited on, also the container box including the discharge opening. Therefore, maintenance work inclusive of cleaning of the container box will have to be performed periodically. If the maintenance work will have to be performed within the vacuum chamber which is provided with a plurality of constituent parts, the workability in maintenance is poor.

### PRIOR ART DOCUMENTS

### Patent Documents

Patent Document 1: JP-A-2014-77193

### SUMMARY OF THE INVENTION

### Problems that the Invention is to Solve

In view of the above-mentioned points, this invention has an object of providing a vapor deposition unit and a vacuum vapor deposition apparatus which is provided with the vapor deposition unit, both being high in versatility and superior in maintenance property.

### Means for Solving the Problems

In order to solve the above-mentioned problems, according to this invention, a vapor deposition unit comprises: a container box for containing therein a vapor deposition material; and a heating means for heating the vapor deposition material inside the container box, the container box having formed through one surface thereof a discharge opening for discharging the vapor deposition material that has been sublimated or vaporized by heating. The vapor deposition unit further comprises a moving means disposed inside a storing chamber whose one surface forms an opening. Provided that a direction facing the opening of the storing chamber is defined as an upper side, the moving means is arranged to move forward or backward in an up-and-down direction the vapor deposition unit inside the storing chamber.

Further, in order to solve the above-mentioned problem, the vacuum vapor deposition apparatus provided with the above-mentioned vapor deposition unit according to this invention further comprises a vacuum chamber having a can-roller. The storing chamber is mounted in position into a mounting opening opened in the vacuum chamber, the mounting being made from a side of the mounting opening. The vapor deposition unit is set in position in a posture in which the discharge opening of the container box lies perpendicularly to an axial line of the can-roller. In this case, there may be employed a constitution in which the distance between the discharge opening and a sheet-like base material that is wound around the can-roller is arranged to be variable by the moving means within a range of up-and-down stroke of the vapor deposition unit such that splashing distribution of the vapor deposition material sublimated or evaporated inside the container box is made adjustable.

According to the above, the arrangement is modularized by providing the storing chamber with the vapor deposition unit. Therefore, regarding the main chamber having, e.g., the can-roller, film-forming is performed on such a portion of the sheet-like base material as is wound around the can-roller, only by mounting the storing chamber from the side of the opening into the mounting opening that has been opened in the main chamber (vacuum chamber) in which the film forming is to be performed, the vapor deposition unit can be set in position in a posture in which the discharge opening of the container box lies perpendicularly to the axial line of the can-roller. Then, by moving the vapor deposition unit by the moving means in the up-and-down direction, the discharge opening can be arbitrarily varied between approaching or departing relative to the can-roller (in turn to such a portion of the sheet-like base material as is wound therearound), i.e., the distance between the discharge opening and an object to be vapor deposited can be arbitrarily varied within a range of the up-and-down stroke of the vapor deposition unit. As a result, it becomes possible to adjust the splashing distribution of the sublimated or evaporated vapor deposition material depending, e.g., on the kind or heating temperature of the vapor deposition material. In addition, at the time of maintenance, since the vapor deposition unit can be removed out of position, together with the storage chamber and all, from the mounting opening, the maintenance performance can be improved as compared with the above-mentioned conventional example.

In the vapor deposition unit of this invention, preferably, the container box is provided with: an outside vessel whose upper surface is open; a supporting frame fixed to an inner wall surface of the outside vessel; an inside vessel disposed on an inside of the supporting frame and containing therein the vapor deposition material; and a lid body covering an opening on an upper surface of the outside vessel and of the inside vessel, respectively, the lid body being adapted to be formed therethrough the discharge opening; and a plurality of supporting pins disposed at predetermined positions of the supporting frame in a manner to protrude inward of the supporting frame such that the inside vessel, when stored inside the outside vessel, is supported by each of the supporting pins. According to this arrangement, since the inside vessel is supported by the supporting pins, heat loss due to heat transfer becomes smaller, thereby enabling to heat the inside vessel more efficiently. In this case, by subjecting the inside surface of the outside vessel to mirror finish, e.g., by electrolytic polishing, the inside surface of the outside vessel serves the purpose of a reflector which reflects the heat of the outside vessel. As a result, the inside vessel can advantageously be heated more effectively by the addition of radiant heat.

By the way, at the time of vapor deposition, there is a case in which the lid body having formed therein the discharge opening is cooled. In such a case, the container box (inside vessel) will give rise to a temperature gradient. As a result, there will be a case in which changes occur in the amount of the vapor deposition material that is sublimated or evaporated inside the container box and subsequently changes occur in dispersion distribution, the changes being corresponding to the amount of heating per unit time from the heating means. As a solution, in this invention, preferably the heating means is constituted by a plurality of sheathed heaters held in position by the supporting frame so as to lie opposite to an outer wall surface of the inside vessel, and the outer wall of the inside vessel is divided into a plurality of regions so that each of the sheathed heaters respectively disposed to lie opposite to respective regions can be charged with a predetermined current value. According to this arrangement, if the amount of heating from the sheathed heaters is adjusted by appropriately setting the current value for the respective regions, the occurrence of temperature gradient in the container box (inside vessel) can advantageously be suppressed from occurring to the best extent possible.

### BRIEF DESCRIPTION OF THE DRAWINGS

FIG. 1 is a sectional view schematically showing a vacuum vapor deposition apparatus which is provided with a vapor deposition unit of this embodiment, in a withdrawn position of the vapor deposition unit.

FIG. 2 is a sectional view schematically showing the vacuum vapor deposition apparatus which is provided with the vapor deposition unit of this embodiment in a vapor deposition position of the vapor deposition unit.

FIG. 3 is a partial sectional view taken along the line III-III in FIG. 2.

FIG. 4 is a perspective view showing a container box of the vapor deposition unit having integrally assembled therewith a heating means.

FIG. 5 is a sectional view taken along the line V-V in FIG. 4.

FIG. 6 is a partially exploded perspective view showing the mechanism of moving the second partition walls in a shielding position.

FIG. 7 is a partially exploded perspective view showing the mechanism of moving the second partition walls in the withdrawn position.

FIG. 8 is a perspective view showing a modified example of the container box of the vapor deposition unit. A partially exploded perspective view showing the mechanism of moving the second partition walls in the withdrawn position.

### MODES FOR CARRYING OUT THE INVENTION

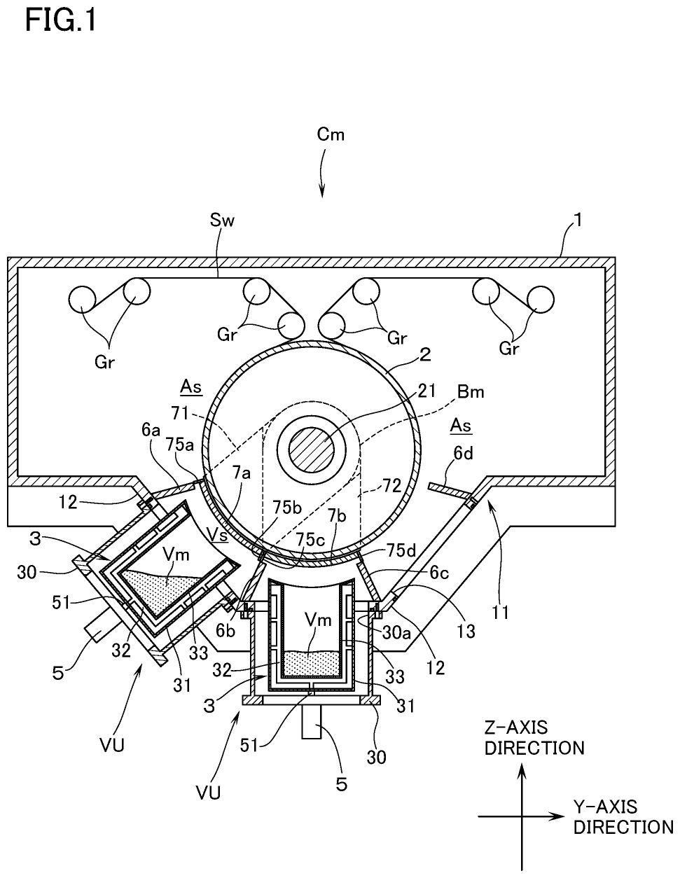

With reference to the accompanying drawings a description will now be made of a vapor deposition unit and a vacuum vapor deposition apparatus of this invention provided with this vapor deposition unit with reference to an example in which this invention is applied to a so-called take-up type of vacuum vapor deposition apparatus. In the following, the description is made on the presumption: that a can-roller is contained inside a main chamber as a vacuum chamber in a posture in which an axial direction of the can-roller coincides with a horizontal direction; that the axial direction is defined as an X-axis direction; that the direction crossing perpendicularly the X-axis on the same horizontal plane is defined as a Y-axis direction; and that a vertical direction crossing perpendicularly the X-axis and the Y-axis is defined as a Z-axis direction. Further, the directions of “up” and “down” shall be based on FIG. 1.

With reference to FIG. 1 to FIG. 3, the vacuum vapor deposition apparatus Cm according to this embodiment is provided with a main chamber 1. The main chamber 1 has connected thereto a vacuum pump which is constituted by a turbo-molecular pump, a rotary pump, and the like (not illustrated) so that a vacuum atmosphere (e.g., 10⁻⁵ Pa) can be formed. In the center of the lower surface of the main chamber 1, there is formed a projected part 11 which projects downward with a profile of semi-regular hexagon as seen in cross-section as shown in FIG. 1. In each of flat planes 12 of the projected part 11 that is elongated in the X-axis direction, there are formed mounting openings 13 facing the can-roller 2 which will be described hereinafter. It is thus so arranged that the vapor deposition units VU of this embodiment can be detachably mounted through the mounting opening 13.

In an upper part of the main chamber 1, there are disposed a plurality of guide rollers Gr in order to guide a sheet-like base material Sw to be transferred from feed rollers (not illustrated) to the can-roller 2, and then to transfer the sheet-like base material Sw, that has gone around the can-roller 2, to take-up rollers (not illustrated). Although not explained particularly by illustration, the main chamber 1 has connected thereto an upstream-side chamber and a downstream-side chamber in a side-by-side relationship with each other. The upstream-side chamber is provided with such a feed roller as is wound by the sheet-like base material Sw so as to feed the sheet-like base material Sw at a constant speed. The downstream-side chamber is provided with such a take-up roller as will take up the sheet-like base material Sw on which a film has been formed as a result of the sheet-like base material's going around the can-roller 2 inside the main chamber 1. Since known art may be referred to as a mechanism from feeding the sheet-like base material Sw down to taking it up, further detailed explanations will be omitted.

The can-roller 2 is provided with a rotary shaft 21. It is thus so arranged that the rotary shaft 21 is rotatably supported inside the main chamber 1 by two bearing devices Bm that are disposed in the X-axis direction (axial direction) at a distance from each other and that the can-roller 2 can be driven for rotation at a given rotational speed by a motor M1 disposed outside the main chamber 1. Although not particularly illustrated in detail, each of the bearing devices Bm is of a type in which an inside bearing on the radially inside and an outside bearing on the radially outside are integrally assembled together to a frame body. The bearing devices Bm are thus so arranged that the inside bearing swingably supports the rotary shaft 21 and that the outside bearing swingably supports a rotary arm of the second partition walls which are described hereinafter. Although not described by illustration, the can-roller 2 has built therein a mechanism for heating or cooling the sheet-like base material Sw in a known manner.

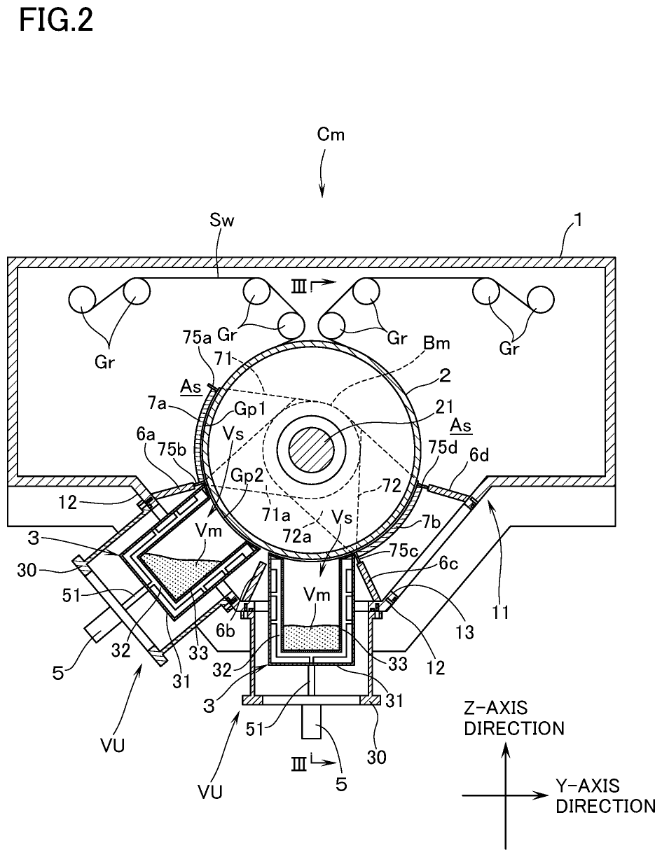

Each of the vapor deposition units Vu has the same construction with each other and is provided with a storing chamber 30 having one surface left open so as to form a communicating opening 30a therein. It is thus so arranged that the storing chamber 30 is respectively mounted on the flat plane 12 of the storing chamber 30 from the outside thereof so as to enclose the mounting opening 13. The storing chamber 30 is provided with a container box 3 which is stored into the communicating opening 30a in a posture in which the phase of the discharge opening 34c, to be described hereinafter, is made to be coincident. The container box 3 has integrally assembled therewith a heating means 4 for heating the vapor deposition material Vm contained therein. As the vapor deposition material Vm there will be used a metallic material or an organic material depending on the thin film to be formed on the sheet-like base material Sw. In this embodiment, a description will be made of an example in which two sets of the vapor deposition units VU are mounted on one (right side in FIG. 1) of the flat planes 12 positioned in a vertical downward direction and on the other (left side in FIG. 1) of the flat planes 12 that is inclined relative to the horizontal plane. However, this invention shall not be limited to the above-mentioned arrangement, but it is also possible, for example, to mount a vapor deposition unit VU on all of the flat planes 12, or to mount the vapor deposition unit VU only on the flat plane 12 that is positioned in the vertical downward direction. In this case, in the mounting opening 13 that is free from mounting therein of the vapor deposition unit VU, there will be mounted a lid body (in FIG. 1 and FIG. 2 lid bodies have been omitted) in order to plug the opening in question.

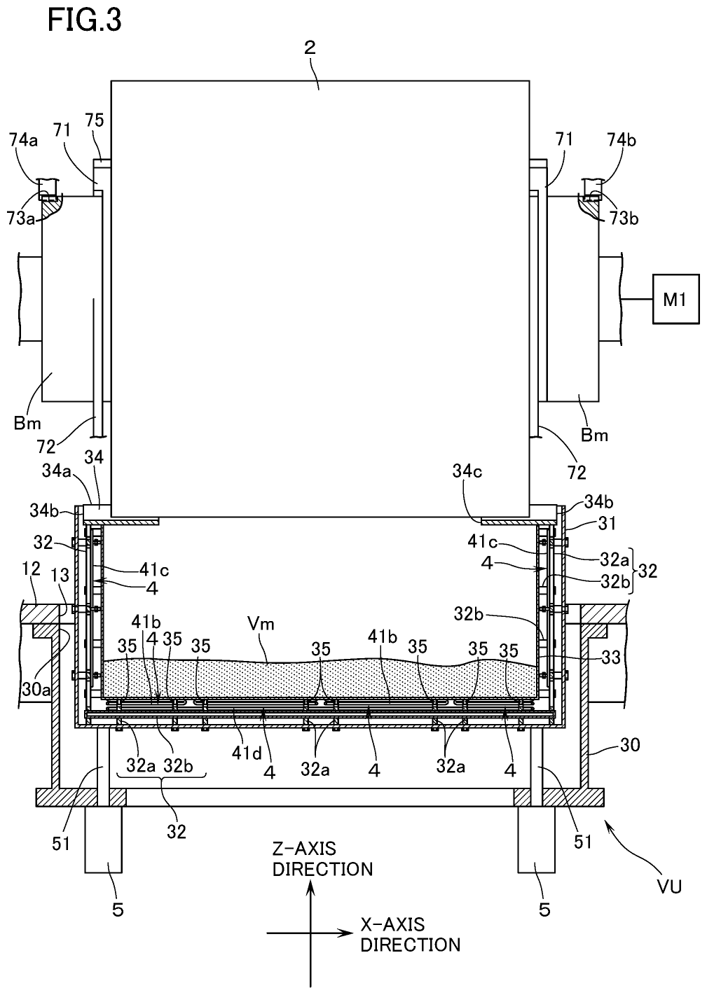

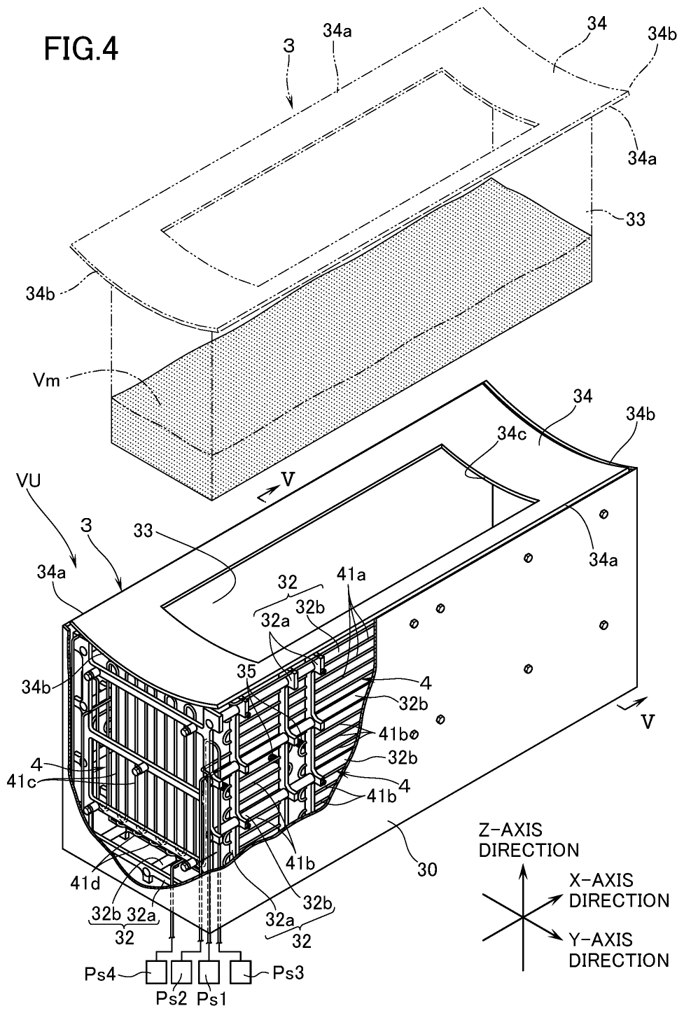

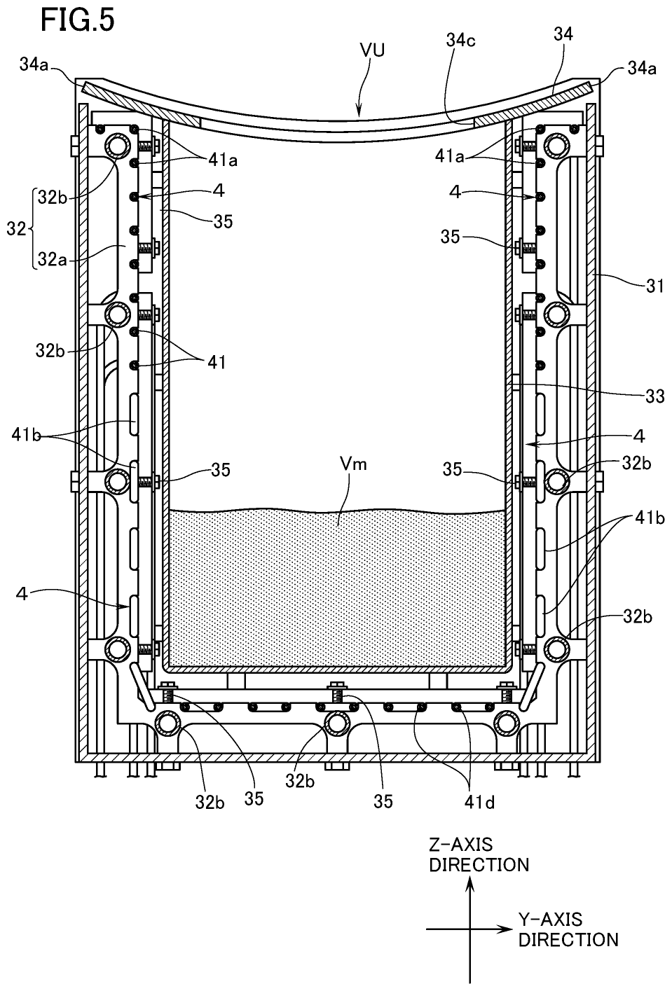

With reference also to FIG. 4 and FIG. 5, a description will be made of an example of a container box 3 mounted on the flat plane 12 which is positioned vertically downward. The container box 3 is made, e.g., of stainless steel and is constituted by: an outside vessel 31 with the upper surface (the surface to face the can-roller 2) being left open; a supporting frame 32 which is fixed to the outside vessel 31 made by assembling plate-like members 32a, 32b into a lattice shape in a manner to cover an inner wall surface of the outside vessel 31 except for the upper surface thereof; an inside vessel 33 which is disposed on the inside of the supporting frame 32 so as to contain therein vapor deposition material Vm; and a lid body 34 which covers the openings in the upper surfaces of the outside vessel 31 and of the inside vessel 33. The outside vessel 31 and the inside vessel 33 have an outline of bottomed rectangular parallelepipeds that are similar to each other as seen in sectional view shown in FIG. 1, and the lengths in the X-axis direction of the outside vessel 31 and of the inside vessel 33 are set equal to, or above, the generatrix length (length in the X-axis direction) (see FIG. 3) of the can-roller 2. The lengths in the Y-axis direction (width) of the outside vessel 31 and the inside vessel 33 are set appropriately taking into consideration the lateral width of the sheet-like base material Sw (specifically, the range of vapor deposition in the X-axis direction relative to the base material Sw), deposition rate, and the like.

In addition, in predetermined positions of the supporting frame 32 there are perpendicularly disposed a plurality of bolts 35, as supporting pins, in a manner to protrude toward the inside of the supporting frame. It is thus so arranged that, when the inside vessel 33 is inserted into the inside of the outside vessel 31, the inside vessel 33 can be supported only by the head portion of each of the bolts 35. The lid body 34 facing the outer peripheral surface of the can-roller 2 is constituted by curving, at a curvature coinciding with the outer peripheral surface of the can-roller 2, a plate body made up of two sets of lateral sides 34a and longitudinal sides 34b respectively elongated in parallel with each other. In the center of the lid body there is opened a single discharge opening 34c that coincides with the opening in the upper surface of the inside vessel 33. The inner edge of the discharge opening 34c is fixed to an upper end of the inside vessel 33 so that the inside vessel 33 and the lid body 34 are made integral with each other. Then, when the inside vessel 33 integral with the lid body 34 as shown in imaginary lines in FIG. 4 is inserted into the outside vessel 31 from the upper-surface opening side, the opening on the upper surface of the outside vessel 31 will be closed by the lid body 34. Further, on an outer wall surface of the storing chamber 30 there is disposed a moving means 5 which is constituted by a direct acting motor and air cylinders. Such a drive shaft 51 of the drive means 5 as penetrates through the outer wall surface so as to extend into the inside of the storing chamber is coupled to the container box 3. According to this arrangement, the container box 3 of the vapor deposition unit VU moves up and down by the moving means 5 in the up-and-down direction (i.e., in the direction in which the hole axis of the discharge opening 34c of the lid body 34 lies perpendicular to the axial line of the can-roller 2).

The heating means 4 is constituted by a plurality of sheathed heaters 41 that are disposed to cover the entirety of both outside wall surfaces in the X-axis direction of, and both outside wall surfaces in the Y-axis direction of, the inside vessel 33, as well as the lower outside wall of the inside vessel 33, and is fixed in position by the supporting frame 32. Then, when the inside vessel 33 is heated by each of the sheathed heaters 41 of the heating means 4 in the vacuum atmosphere in a state in which the inside vessel 33 containing therein the vapor deposition material Vm is inserted into the outside vessel 31, the vapor deposition material Vm will be sublimated or evaporated within the inside vessel 33. The vapor deposition material thus sublimated or evaporated will be discharged out of the discharge opening 34c. Here, in case vapor deposition is being performed while the sheet-like base material Sw is cooled by the cooling mechanism housed in the can-roller 2, there is a possibility that the temperature gradient in the up-and-down direction may be generated in the inside vessel 33 because the lid body 34 is cooled by radiation cooling. In this embodiment, the outside walls of the inside vessel 33 are divided into four regions of the upper part of both the outside walls in the Y-axis direction of the inside vessel 33; the central part of both the outside walls in the Y-axis direction of the inside vessel 33; the lower parts of both the outside walls in the Y-axis direction of the inner vessel 33 and the lower outside walls of the inside vessel 33 and lower outside wall of the inside vessel 33; and both the outside walls in the X-axis direction of the inside vessel 33. The sheathed heaters to face each of the regions are defined to be each of the first through the fourth heaters 41a, 41b, 41c, 41d. Each of the first through the fourth sheathed heaters 41a, 41b, 41c, 41d is respectively connected to each of the first through the fourth power supply devices Ps1, Ps2, Ps3, Ps4. In this arrangement, in energizing each of the first through the fourth sheathed heaters 41a, 41b, 41c, 41d by each of the first through the fourth power supply devices Ps1, Ps2, Ps3, Ps4, each of the sheathed heaters is arranged to be energized at different current values respectively. According to this arrangement, by adjusting the heating amount from each of the first through the fourth sheathed heaters 41a, 41b, 41c, 41d by appropriately setting the current values, the temperature gradient can advantageously be suppressed from occurring in the inside vessel 33 to the best extent possible.

According to the above-mentioned embodiment, the storing chamber 30 is provided with a vapor deposition unit VU into modularization. Therefore, only by mounting in position the storing chamber 30 into the mounting opening 13 of the main chamber 1, the vapor deposition unit VU can be set in position in a posture in which the discharge opening 34c faces the sheet-like base material Sw that is wound around the can-roller 2. In addition, since the inside vessel 33 is supported by the head portion of each of the bolts 35, the thermal loss due to heat transmission can be made smaller, resulting in more efficient heating of the inside vessel 33. In this case, by subjecting the inner surface of the outside vessel 31 to, e.g., mirror finish by electrolytic polishing, the inner surface of the outside vessel 31 serves the purpose of a reflector to reflect the heat at the time of heating the inside vessel 33 with each of the sheathed heaters 41. As a result, by the addition of the radiant heat the inside vessel 33 can be more efficiently heated. The filling factor of the container box 3 relative to the inside vessel 33 is appropriately set within a range of 20% to 40% taking into consideration, e.g., the kind of the vapor deposition material Vm, or the variation in the deposition rate accompanied by the fluctuation in the internal pressure in the inside vessel 33 during the time to the entire sublimation or evaporation of the vapor deposition material Vm filled into the container box 3.

Furthermore, since the moving means 5 is disposed on the outer wall surface of the storing chamber 30, once the storing chamber 30 has been mounted in position into the mounting opening 13, the moving means 5 will make the container box 3 of the vapor deposition unit VU free to move between: a separated position, as shown in FIG. 1, in which the lid body 34 is away from the outer peripheral surface of the can-roller 2; and a vapor deposition position, as shown in FIG. 2, in which the lid body 34 comes closer to the outer peripheral surface of the can-roller 2 while leaving a gap (hereinafter this gap is defined as a “second gap Gp2”) that is curved at the above-mentioned curvature. At this time, within a range of stroke of the moving means 5 the distance between the discharge opening 34c and the sheet-like base material Sw that is wound around the can-roller 2 (i.e., the magnitude of the second gap Gp2) can be arbitrarily varied. The second gap Gp2 becomes a vapor deposition space to be partitioned by the lid body 34 and such a portion of the can-roller 2 as will face the lid body 34.

Inside the main chamber 1 and in a position around the can-roller 2, there are respectively provided such stationary partition walls 6a, 6b, 6c, 6d as are fixed to the inner wall of the main chamber 1 in a manner to be elongated in the X-axis direction. By means of the stationary partition walls 6a, 6b, 6c, 6d there are respectively defined, inside the main chamber 1, vapor deposition chambers Vs in communication with the storing chambers 30 and having contained therein the vapor deposition units VU. In this case, although not explained by particularly illustrating, it is preferable to arrange so that the vapor deposition chamber Vs can be evacuated independent of the main chamber 1. Inside the main chamber 1 there are respectively further provided second partition walls 7a, 7b (see FIG. 2) which cover the outer cylinder part at the above-mentioned curvature through a gap (hereinafter, this gap is defined as “a first gap Gp1”) that is curved at the above-mentioned curvature along the outer cylinder part of the can-roller 2. The vapor deposition chamber Vs and such an adjacent chamber As (e.g., transfer space for the sheet-like base material Sw) inside the main chamber 1 as is adjacent to the vapor deposition chamber Vs are brought into communication with each other with the first gap Gp1 serving as a boundary. It is thus so arranged that the conductance value between the vapor deposition chamber Vs and the adjacent chamber As can be determined by the second partition walls 7a, 7b.

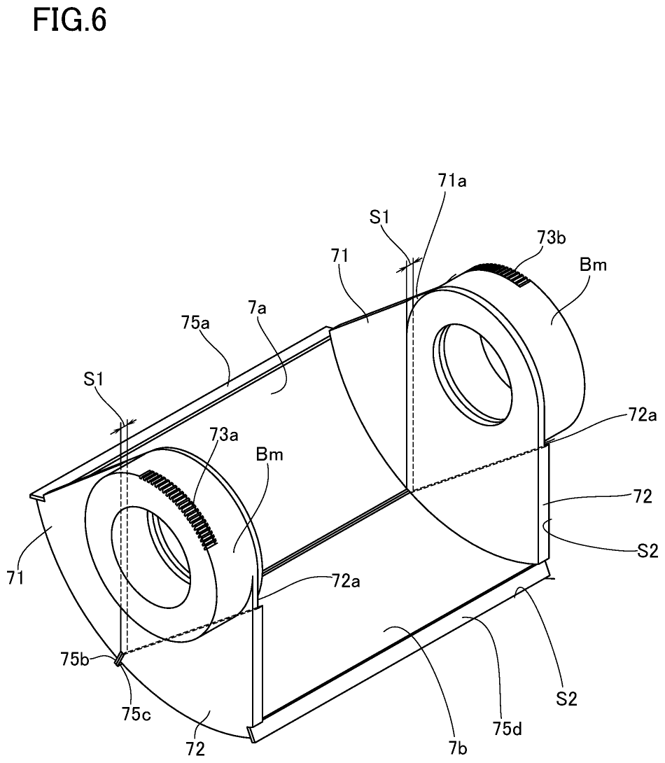

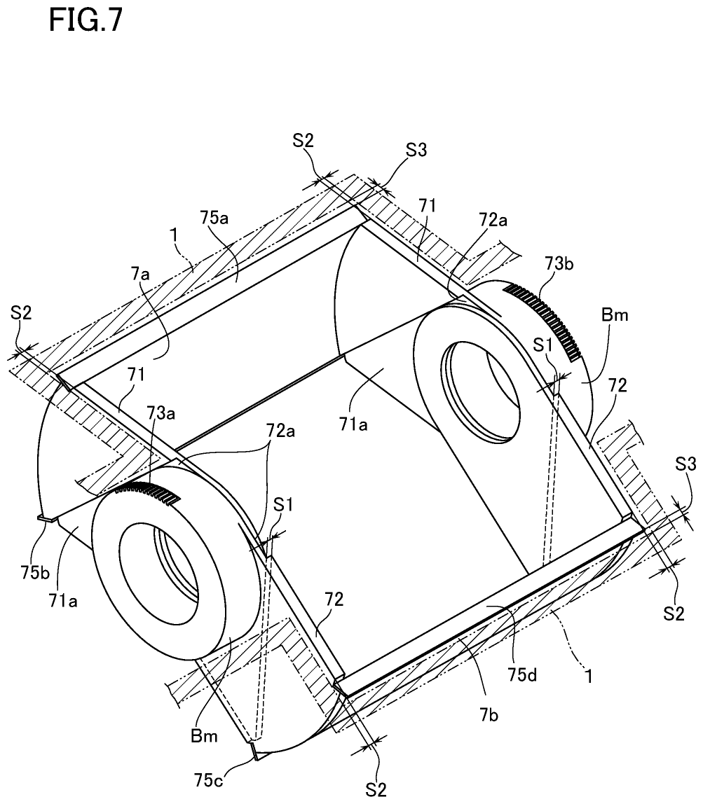

With reference also to FIG. 6 and FIG. 7, the second partition walls 7a, 7b are constituted by bending plate members, e.g., stainless steel plate members, at the above-mentioned curvature and are respectively installed between a front end of each of swing arms 71, 72 swingably supported by outer bearings (not illustrated) of each of the bearing devices Bm that are disposed at a distance from each other in the X-axis direction. The outer peripheral surface of each of the bearing devices Bm has respectively formed therein set of teeth 73a, 73b at a predetermined pitch. Each set of teeth 73a, 73b is in mesh with racks 74a, 74b that are respectively driven by a motor (not illustrated). When the racks 74a, 74b are moved by the motor in the Y-axis direction, the second partition walls 7a, 7b swing along the outer peripheral surface of the can-roller 2 in the directions that are opposite to each other. In this case, such surfaces of respective swing arms 71, 72 as face each other are subjected to counter boring. By overlapping the counterbored surfaces 71a, 71b while leaving the first space part S1 therebetween, both the second partition walls 7a, 7b are arranged to be respectively moveable while maintaining the first gap part Gp1 in the periphery of the can-roller 2. According to this arrangement, the second partition walls 7a, 7b become rotatable, with the rotary shaft 21 of the can-roller 2 serving as the center of rotation, between: a shielding position in which such a portion of the can-roller 2 as is faced by the discharge opening 34a of the lid body 34; and a withdrawn position in which the second partition walls 7a, 7b are circumferentially away from the vapor deposition units VU. In this case, in the route of rotation of the second partition walls 7a, 7b inclusive of the shielding position and the withdrawn position of the second partition walls 7a, 7b, the inner wall surface of the main chamber 1 is formed such that: there is formed a second space part S2 between the end surface in the X-axis direction (axial direction) of each of the second partition walls 7a, 7b and such inner wall surface of the main chamber 1 as lies opposite to the end surface; and that a third space part S3 is formed between the outer peripheral surface of each of the second partition walls 7a, 7b and the inner wall surface of the main chamber 1.

When the vapor deposition unit VU is in the separated position and the second partition walls 7a, 7b are in the shielding position respectively as shown in FIG. 1, the vapor deposition chamber Vs and the adjacent chamber As are in communication with each other only through the first space part S1 through the third space part S3 (see FIG. 7). However, the vapor deposition chamber Vs and the adjacent chamber As can surely be separated in terms of atmosphere by appropriately setting, e.g., the area of the counter-bored surfaces 71a, 71b so that the conductance value in the first space part S1 attains a predetermined value from: the size of such second space part S2 and the third space part S3 as are unavoidable from the viewpoint of the constitution of the apparatus; or the pressure difference between such a pressure in the adjacent chamber As and the pressure in the vapor deposition chamber Vs as can be empirically obtained in advance. On the other hand, in a state in which the second partition walls 7a, 7b have been moved to the withdrawn position from the state as shown in FIG. 1, the vapor deposition chamber Vs and the adjacent chamber As are in communication with each other through the first gap Gp1 in addition to the first space part through the third space part S1-S3. However, in the same manner as above, from: the pressure difference between the pressure in the adjacent chamber As and the pressure in the vapor deposition chamber Vs; or the size of such first gap Gp1 as is unavoidable for the sheet-like base material Sw to pass therethrough as a result of the rotation of the can-roller 2, the vapor deposition chamber Vs and the adjacent chamber As can surely be separated in terms of atmosphere if the circumferential lengths of the second partition walls 7a, 7b are appropriately set so that the conductance value in the first gap Gp1 becomes a predetermined value. Then, even if the vapor deposition units VU have been moved to the vapor deposition position, and the second partition walls 7a, 7b have been moved to the withdrawn positions, respectively, as shown in FIG. 2, the second gap Gp2 as the vapor deposition space can maintain the state in which the atmosphere is separated from that in the adjacent chamber As. Although not explained by particularly illustrating, it may be so arranged: that a coolant circulation passage for circulating therein a coolant is formed in the second partition walls 7a, 7b; and that, after having moved the second partition walls 7a, 7b to the shielding position, the coolant is circulated in the circulation passage through the bearing device Bm so as to cool the second partition walls 7a, 7b to a predetermined temperature.

Further, at an end surface in the circumferential direction of each of the second partition walls 7a, 7b, there is respectively mounted a partition wall plate 75a, 75b, 75c, 75d having a length equivalent to or above the generatrix length of the can-roller 2. In the shielding position of the second partition walls 7a, 7b as shown in FIG. 1, each of the partition wall plates 75a, 75b, 75c, 75d comes into contact with the radially inner end surface of the stationary partition walls 6a, 6b, 6c, respectively. On the other hand, in the withdrawn position of the second partition walls 7a, 7b as shown in FIG. 2 in which the second partition walls 7a, 7b are swung in a direction away from each other, the partition wall plate 75b of one 7a of the second partition walls comes into contact with the stationary partition wall 6a, and the partition wall plate 75c of the other 7b of the second partition walls 7b comes into contact with the stationary partition wall 6c, respectively. And in the withdrawn position of the second partition walls 7a, 7b, if the container box 3 of the vapor deposition unit VU is proceeded into the vapor deposition position, each of the lateral sides 34a, 34a of the lid body 34 comes into contact with each of the respective partition wall plates 75a, 75d of each of the second partition walls 7a, 7b so that the first gap Gp1 and the second gap Gp2 come to be communicated with each other around the periphery of the can-roller 2 (see FIG. 2).

In case vapor deposition is performed on such a part of the sheet-like base material Sw as is wound around the can-roller 2, while the sheet-like base material Sw is being travelled in the above-mentioned vacuum vapor deposition apparatus Cm, first, the storing chamber 30 having built therein the vapor deposition unit VU is mounted in position into the mounting opening 13 of the main chamber 1 from the outside thereof. Then, the main chamber 1 including the vapor deposition chamber Vs is evacuated to a predetermined pressure. At this time the container box 3 of the vapor deposition unit VU is moved to the separated position, and each of the second partition walls 7a, 7b is moved to the shielding position, respectively. In this state the vapor deposition material Vm is heated by the heating means 4. Then, the vapor deposition material Vm inside the container box 3 will be sublimated or evaporated. The amount of vapor deposition will become gradually stabilized depending on the amount of heating by the heating means 4. By that time, part of the vapor deposition material that has been sublimated or evaporated inside the container box 3 will be discharged from the discharge opening 34c of the lid body 34 toward the sheet-like base material Sw, thereby getting adhered to the second partition walls 7a, 7b, respectively. Then, once the amount of vapor deposition of the vapor deposition material Vm inside the container box 3 has been stabilized, each of the second partition walls 7a, 7b is respectively moved to the withdrawn position and, thereafter, the container box 3 of the vapor deposition unit VU is moved to the deposition position. According to these operations, the vapor deposition space is formed inside the main chamber 1. When the sheet-like base material Sw is transported by the base material transportation means, the vapor deposition material to be discharged out of the discharge opening 34c will get adhered to, and deposited on, such a portion of the sheet-like base material Sw as is wound around the can-roller 2, thereby performing continuous vapor deposition.

At the time of vapor deposition, the vapor deposition chamber Vs and the adjacent chamber As are separated in terms of atmosphere. Therefore, degree of closure can be increased in the passage from the discharge opening 34c, through the second gap Gp2 as the vapor deposition space and through the first gap Gp1 to the adjacent space As. As a result, even if the opening area of the discharge opening 34c is set at relatively large in order to obtain an extremely high film-forming rate, the vapor deposition material to be discharged out of the discharge opening 34c comes, on the one hand, to get adhered to, and deposited on, a portion of the sheet-like base material Sw through the second gap Gp2 before spreading to a wide range. On the other hand, out of the vapor deposition material that is discharged out of the discharge opening 34c to the second gap Gp2, such a vapor deposition material as fails to contribute to the vapor deposition on the base material Sw comes to be returned to the inside vessel 33. According to this arrangement, the material that wraps around into the main chamber 1 inclusive of the adjacent chamber As so as to get adhered to the portion (part) other than the sheet-like base material Sw can be suppressed to the maximum extent possible and, as a result, waste of the vapor deposition material Vm can be prevented. Lastly, at the time of maintenance work, the maintenance work will be performed in a state in which the storing chamber 30 has been removed out of the mounting opening 13 of the main chamber 1.

Descriptions have so far been made of an embodiment of this invention, but this invention shall not be limited to the one according to the above embodiment. Various modifications are possible within a range not departing from the substance of this invention. In the above-mentioned embodiment, a description has been made of an arrangement in which the vapor deposition unit VU is arranged such that the container box 3 of the vapor deposition unit VU is directly moved back and forth by the moving means 5 such as a direct-drive motor, air cylinders, etc. relative to the outer peripheral surface of the can-roller 2. A known guide mechanism to guide the movement may be disposed inside the storing chamber 30. Further, in the above-mentioned embodiment, a description was made of an example in which the container box 3 of the vapor deposition unit VU is arranged to be moved in the up-and-down direction, i.e., in the direction in which the opening axis of the discharge opening 34c of the lid body 34 is arranged to extend perpendicularly to the axial line of the can-roller 2. However, it shall not be limited to the above but, for example, taking into consideration the dispersion distribution of the vapor deposition material Vm to be discharged out of the discharge opening 34c, modifications can appropriately be made.

Further, in the above-mentioned embodiment, a description was made of an example in which a single discharge opening 34c is provided. But without being limited to the above, there may be employed an arrangement in which a plurality of pieces of cylindrical discharge openings are arrayed at a predetermined distance from one another in the widthwise direction of the sheet-like base material Sw. In this case, there are cases where the opening axis of each of the cylindrical discharge openings not only perpendicularly crosses the axial line of the can-roller 2, but also each of the discharge openings is formed in the lid body so as to be inclined at a predetermined angle. In order to correspond to this, the posture of the vapor deposition unit inside the storing chamber and the direction of movement of the vapor deposition unit can appropriately be changed. Further, in the above-mentioned embodiments, a description was made of an example having a can-roller 2 in the main chamber 1 in which film forming is performed on such a portion of the sheet-like base material Sw as is wound around the can-roller 2, but this invention shall not be limited to the above. For example, this invention can also be applied to a vacuum vapor deposition apparatus in which an object to be vapor deposited is defined as a rectangular substrate and which has a transportation mechanism for sequentially transporting a plurality of substrates. At this time, the vapor deposition unit is set in position inside the storage chamber in a posture in which, e.g., the discharge opening of the container box is perpendicular to the film-forming surface of the substrate.

By the way, in the above-mentioned embodiment, when the container box 3 of the vapor deposition unit VU is moved to the vapor deposition position, the vapor deposition material Vm is discharged out of the discharge opening 34c, and vapor deposition is performed on such a portion of the sheet-like base material Sw as is wound around the can-roller 2, the lid body 34 itself serves the function of a mask which defines the range of vapor deposition on such a portion of the sheet-like base material Sw. On the other hand, there is a case in which the lid body 34 is thermally deformed (thermal expansion) because it is integrally fixed to an upper end of the inside vessel 33, despite the fact that the lid body 34 is cooled by radiation cooling. At this time, since the lid body 34 is set equal to or above the length of the generatrix (X-axis direction) of the can-roller 2, thermal deformation will take place, depending on the thermal conditions at that time, more remarkably in the X-axis direction than in the Y-axis direction.

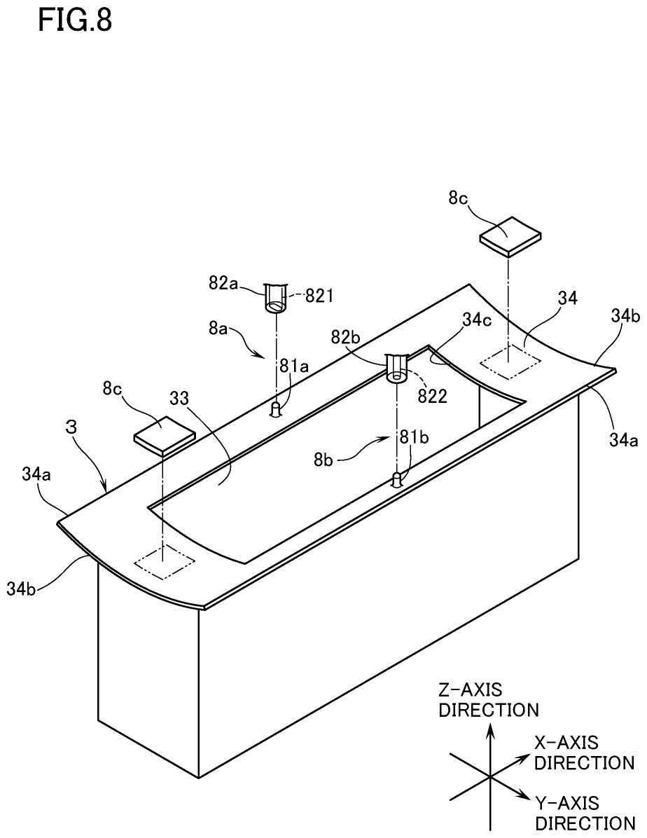

Relating to a modified example, as shown in FIG. 8, a restriction means is disposed in a manner to allow the lid body 34 to displace (to thermally deform) in the Y-axis direction and to allow it to rotate about the Z-axis, but does not allow deformation in the X-axis direction and in the Z-axis direction. The restriction means is, e.g., provided with: both of a first and a second restriction parts 8a, 8b which are disposed in a central region in the X-axis direction in a manner to lie opposite to outer edges of the discharge opening 34; and a pair of third restriction parts 8c which are disposed on outer edges on both end parts in the X-axis direction of the discharge opening 34. Each of the first and the second restriction parts 8a is provided with: columnar projections 81a, 82a which are disposed in predetermined positions on an upper surface of the discharge opening 34; and receiving members 82a, 82b respectively having receiving holes 821, 822 which are fixedly placed on the main chamber (not illustrated) to correspond to each of the projections 81a, 82a, and which respectively receive each of the projections 81a, 82a.

When the container box 3 of the vapor deposition unit VU is moved by the moving means 5 to a vapor deposition position, each of the projections 81a, 81b is tightly fitted into each of the receiving holes 821, 822. In this case, the receiving hole 821 has an oblong contour which is longer in the Y-axis direction so that the displacement in the Y-axis direction is allowed but the deformation in the X-axis direction is not allowed. Further, the receiving hole 82a has a circular contour such that the receiving hole 822 allow the rotation in the Z-axis direction but the displacement in the Z-axis direction is not allowed. In addition, the third restriction parts 8c are constituted by urging pieces which are curved at a curvature coinciding with that of the lid body 34. When the container box 3 of the vapor deposition unit VU is moved to the vapor deposition position, the third restriction parts 8c come into contact with the lid body 34 so as to restrict the displacement of the lid body 34 in the Z-axis direction. By the way, the restriction means may alternatively be disposed between the lower surface of the lid body 34 and the upper surface of the supporting frame 32.

### EXPLANATION OF MARKS

Sw sheet-like base material (object to be vapor deposited)
Vm vapor deposition material
VU vapor deposition unit
1 main chamber (vacuum chamber)
13 mounting opening
3 container box
30 storing chamber
30a communicating opening
31 outside vessel
32 supporting frame
33 inside vessel
34 lid body
34c discharge opening
35 bolt (supporting pin)
4 heating means
41a, 41b, 41c, 41d sheathed heater
5 moving means

1. A vapor deposition unit comprising:
a container box for containing therein a vapor deposition material; and a heating means for heating the vapor deposition material inside the container box, the container box having formed through one surface thereof a discharge opening for discharging the vapor deposition material that has been sublimated or vaporized by heating,
wherein the vapor deposition unit further comprises a moving means disposed inside a storing chamber whose one surface forms an opening, provided that a direction facing the opening of the storing chamber is defined as an upper side, the moving means being arranged to move forward or backward in an up-and-down direction the vapor deposition unit inside the storing chamber, and
wherein the container box is provided with: an outside vessel whose upper surface is open; a supporting frame fixed to an inner wall surface of the outside vessel; an inside vessel disposed on an inside of the supporting frame and containing therein the vapor deposition material; and a lid body covering an opening on an upper surface of the outside vessel and of the inside vessel, respectively, the lid body being adapted to be formed therethrough the discharge opening; and a plurality of supporting pins disposed at predetermined positions of the supporting frame in a manner to protrude inward of the supporting frame such that the inside vessel, when stored inside the outside vessel, is supported by each of the supporting pins.

2. (canceled)

3. The vapor deposition unit according to claim 1, wherein
the heating means is constituted by a plurality of sheathed heaters held in position by the supporting frame so as to lie opposite to the outer wall surface of the inside vessel, and wherein the outer wall of the inside vessel is divided into a plurality of regions so that each of the sheathed heaters respectively disposed to lie opposite to respective regions can be charged with a predetermined current value.

4. A vacuum vapor deposition apparatus provided with the vapor deposition unit according to claim 1, further comprising a vacuum chamber having a can-roller,
wherein the storing chamber is mounted in position into a mounting opening opened in the vacuum chamber, the mounting being made from a side of the mounting opening, and wherein the vapor deposition unit is set in position in a posture in which the discharge opening of the container box lies perpendicularly to an axial line of the can-roller.

5. The vacuum vapor deposition apparatus according to claim 4, wherein a distance between the discharge opening and a sheet-like base material that is wound around the can-roller is arranged to be variable by the moving means within a range of up-and-down stroke of the vapor deposition unit such that splashing distribution of the vapor deposition material sublimated or evaporated inside the container box is made adjustable.

6. The vacuum vapor deposition apparatus according to claim 4, provided that an axial direction of the can-roller is defined as an X-axis direction, that an up-and-down direction is defined as a Z-axis direction, and that a vertical direction crossing perpendicularly the X-axis and the Z-axis is defined as a Y-axis direction, wherein the lid boby is elongated in the X-axis direction and has a plate shape, and
wherein a restriction means is disposed in a manner to allow the lid body to thermally deform in the Y-axis direction and to allow the lid body to rotate about the Z-axis, but restrict displacement of the lid body in the X-axis direction and in the Y-axis direction.

7. The vacuum vapor deposition apparatus according to claim 6, wherein the restriction means is provided with: a first and a second restriction parts which are disposed in a central region in the X-axis direction in a manner to lie opposite to outer edges of the discharge opening; and third restriction parts which are disposed on outer edges on both end parts in the X-axis direction of the discharge opening.
